(19) United States
(12) Patent Application Publication
(10) Pub. No.: US 2005/0206012 A1
(43) Pub. Date: Sep. 22, 2005

(54) Stress and force management techniques for a semiconductor die

(76) Inventors: Warren M. Farnworth, Nampa, ID (US); William M. Hiatt, Eagle, ID (US); Tim E. Murphy, Boise, ID (US); John L. Caldwell, Meridian, ID (US); Michael Slaughter, Boise, ID (US); David R. Hembree, Boise, ID (US); Jamie J. Wanke, Boise, ID (US)

Correspondence Address: TRASK BRITT, P.O. BOX 2550, SALT LAKE CITY, UT, 84110, US

(21) Appl. No.: 10/801,205

(22) Filed: Mar. 16, 2004

(51) Int. Cl. H01L 23/48

(52) U.S. Cl. 257/782

(57) ABSTRACT

Stress and force management techniques for a semiconductor die to help compensate for stress within the semiconductor die and to help compensate for forces applied to the semiconductor die to minimize damage thereto.

### BACKGROUND OF THE INVENTION

1. Field of the Invention

The present invention relates to stress and force management techniques for semiconductor dice to help compensate for stress within the semiconductor dice and forces applied to the semiconductor dice to minimize damage thereto.

2. State of the Art

Along with the increased performance of a semiconductor die, the physical size of the semiconductor die typically decreases for a variety of reasons, such as to occupy a minimum amount of volume, to reduce the lengths of circuits of the semiconductor die, to decrease the size of components of the semiconductor die, to decrease the thickness of the layers of materials used to form the semiconductor die, etc. With such increased performance and such smaller physical size of the semiconductor die, inherent stresses within the semiconductor die caused by the architecture of the various circuits, the materials used to form the various circuits and components, the size, shape and location of the circuits and components, etc. increase, particularly due to the stresses inherent in the formation of the various circuits and components of the semiconductor die as well as the heat generated by the semiconductor die during the operation thereof. With increased stresses in the semiconductor die, the semiconductor die tends to become distorted more easily, tends to be more subject to damage during the various manufacturing operations for forming the components and circuitry of the semiconductor die, during handling, and during any packaging processes by the materials used in the processing, as well as tends to be subject to other problems associated with any semiconductor die having increased performance and a minimum size configuration.

For instance, U.S. Pat. Nos. 6,063,650 and 6,277,225 are directed to reduced stress assemblies for a semiconductor die using a leads-over-chip type lead frame to help minimize stress and damage to the circuits and components of the semiconductor die cause by filler material in the encapsulating material used during packaging operations penetrating through passivation layers on the active surface of the semiconductor die to damage the circuits and components thereof. However, as the size of the semiconductor die decreases, any portion of a lead frame or a substrate connected thereto provides less clearance between the lead frame or substrate and the semiconductor die for encapsulation material and filler material therein to flow without stressing or damaging the circuitry and components of the semiconductor die. Similarly, as the size of the semiconductor die decreases, the distance any foreign material must penetrate through passivation layers on the active surface of the semiconductor die to cause problems with the circuitry or components of the semiconductor die also decreases.

Additionally, as the thickness of the substrate of a semiconductor die becomes thinner, the stresses caused by the circuits and components of the semiconductor die distort the semiconductor die, making any handling and packing of the semiconductor die more difficult without damage thereto. Associated with such smaller semiconductor die having increased performance are increased stresses caused during the uneven heating of portions of the semiconductor die from the circuits and components in such portions that distort the semiconductor die, with potentially catastrophic results to the semiconductor die. Yet other problems arise when trying to make connections to the bond pads of a smaller semiconductor die due to the forces generated during any process to make any connections being distributed over a smaller portion of the semiconductor die to potentially damage such an area or any circuit and/or component of the semiconductor die. Also, any forces caused by any mismatch in the thermal coefficient of expansion between different materials used for a semiconductor die and a member to which the semiconductor die is connected are applied to a smaller area of the semiconductor die, causing increased stresses in such area. Yet further, wafer level packaging, commonly referred to as flip chip packaging, and flip chip in package use an additional metal layer and polyimide layers at the end of the conventional wafer fabrication process which add to the stresses of a semiconductor die. One layer of such a process is the redistribution metal layer used for different circuit patterns for connections to the semiconductor die. The redistribution metal layer is typically applied by sputtering a blanket aluminum film, or any suitable metal film, which is subsequently patterned and etched to create traces that are connected to bond pads of a semiconductor die to redistribute and form circuits leading to outer lead bond pads located over the circuitry of the semiconductor die. The redistributed outer lead bond pads are then used to electrically connect the redistribution layer of metal traces to traces and/or connection pads of a substrate. A typical process for the redistribution of circuits and bond pads of a semiconductor die and under bump metallization processes being described in U.S. Pat. No. 6,147,413. A typical method of forming a chip scale package using flip chip technology being described in U.S. Pat. No. 6,287,893.

Accordingly, the stresses caused by the circuitry and components, and the materials used in the circuitry and components of a semiconductor die, and the forces applied to a semiconductor die need to be addressed to minimize damage to the semiconductor die for a variety of reasons.

### BRIEF SUMMARY OF THE INVENTION

The present invention relates to stress and force management techniques for semiconductor dice to help compensate for stress within the semiconductor dice and forces applied to the semiconductor dice to minimize damage thereto.

### BRIEF DESCRIPTION OF THE SEVERAL VIEWS OF THE DRAWINGS

In the drawings, which illustrate what is currently considered to be the best mode for carrying out the invention:

FIG. 1 is a view of the active surface of a first semiconductor die having a plurality of bond pads thereon;

FIG. 2 is a view of the active surface of a second semiconductor die having a plurality of bond pads thereon;

FIG. 3 is a view of the inactive surface of a semiconductor die;

FIG. 4 is a side view of a semiconductor die mounted on a substrate according to one embodiment of the present invention;

FIG. 5 is a side view of a semiconductor die mounted on a substrate according to another embodiment of the present invention;

FIG. 6 is a view of a thermal map of a semiconductor die;

FIG. 7 is a side view of a portion of a semiconductor die according to another embodiment of the invention;

FIG. 8 is a top view of the inactive surface of a semiconductor die according to the embodiment of the present invention shown in drawing FIG. 7;

FIG. 9 is a side view of a semiconductor die located on a substrate according to another embodiment of the present invention;

FIG. 10 is a side view of a semiconductor die located on a substrate according to another embodiment of the present invention;

FIG. 11 is a view of the active surface of a semiconductor die according to another embodiment of the present invention;

FIG. 12 is a top view of a substrate according to another embodiment of the present invention;

FIG. 13 is a side view of a semiconductor die located on a substrate according to the embodiments of the present invention shown in drawing FIGS. 11 and 12.

FIG. 14 is a cross-sectional view of a portion of a semiconductor die according to another embodiment of the present invention; and

FIG. 15 is a top view of a semiconductor die according to another embodiment of the present invention shown in drawing FIG. 14.

### DETAILED DESCRIPTION OF THE INVENTION

Referring to drawing FIG. 1, shown is the active surface 12 of a semiconductor die 10 having a plurality of bond pads 14 thereon located in a pattern of four columns of bond pads 14. The four columns of bond pads 14 are generally arranged in locations in the central portion and the outer portions of the active surface 12. Alternatively, the bond pads 14 may be described as being arranged in ten rows of bond pads 14 on the active surface 12 in the central portion and outer portions of the active surface 12 of the semiconductor die 10. The bond pads 14 either may be connected or not connected to circuitry and components (not shown) of the semiconductor die 10, as desired. The semiconductor die 10 may be any type of semiconductor die 10 such as a memory device, a processor, a digital signal processing-type device, etc. The bond pads 14 may be placed in any desired pattern on the active surface 12 of the semiconductor die 10. The size and shape of the bond pads 14 may be as desired. Similarly, the bond pads 14 may be formed of any suitable material or any number of layers of materials for any type of connections being made therewith for both mechanical and electrical purposes.

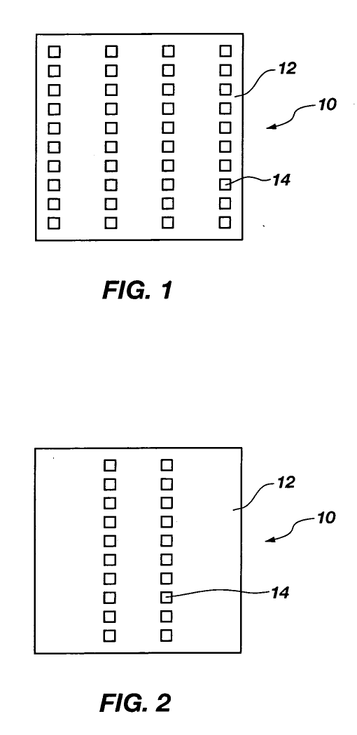

Referring to drawing FIG. 2, the semiconductor die 10 is shown having a plurality of bond pads 14 on the active surface thereof arranged in a second pattern of two columns of bond pads 14. The two columns of bond pads 14 are arranged generally in the central portion of the active surface 12 of the semiconductor die 10. Alternatively, the bond pads 14 may be described as being arranged in ten rows in the central portion of the semiconductor die 10. As before, the bond pads 14 either may be connected or not connected to circuitry and components (not shown) of the semiconductor die 10. As stated previously, the semiconductor die 10 may be any type of semiconductor die 10 such as a memory device, a processor, a digital signal processing-type device, etc. The bond pads 14 may be placed in any desired pattern on the active surface 12 of the semiconductor die 10. The size and shape of the bond pads 14 may be as desired. Similarly, the bond pads 14 may be formed of any suitable material or any number of layers of materials for any type of connections being made therewith for both mechanical and electrical purposes.

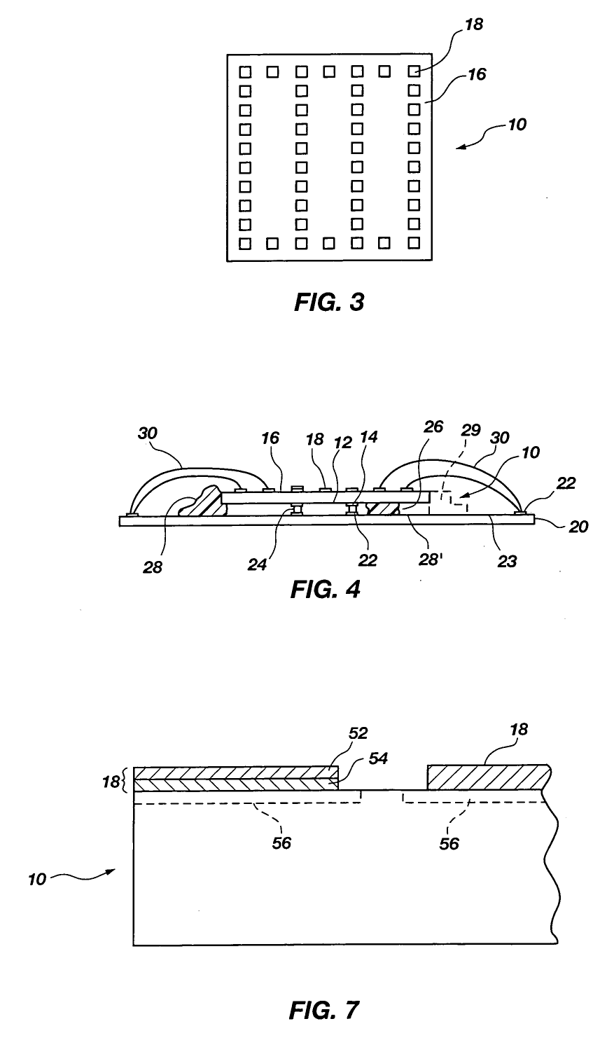

Referring to drawing FIG. 3, the semiconductor die 10 is shown having a plurality of bond pads 18 generally arranged in four columns located on the inactive surface or backside 16 of the semiconductor die 10. The four columns of bond pads 18 are generally arranged in locations in the central portion and the outer portions of the inactive surface 16. Alternatively, the bond pads 18 may be described as being arranged in ten rows of bond pads 18 in the central portion and outer portions of the inactive surface 16 of the semiconductor die 10. The bond pads 18 either may be connected or not connected to circuitry and components (not shown) of the semiconductor die 10. The semiconductor die 10 may be any type of semiconductor die 10 such as a memory device, a processor, a digital signal processing-type device, etc. The bond pads 18 may be placed in any desired pattern on the inactive surface 16 of the semiconductor die 10. The size and shape of the bond pads 18 may be as desired. Similarly, the bond pads 18 may be formed of any suitable material or any number of layers of materials for any type of connections being made therewith for both mechanical and electrical purposes.

Referring to drawing FIG. 4, shown is a semiconductor die 10 located on a substrate 20 having a plurality of contact pads 22 located on a surface 23 thereof at desired locations. The contact pads 22 are connected to circuits (not shown) located on a surface of substrate 20, or located in the substrate 20, or located on both surfaces of the substrate 20 and in the substrate 20 as desired. The semiconductor die 10 has the pattern of bond pads 14 located on the active surface 12 thereof as shown in drawing FIG. 2. The semiconductor die 10 also has a plurality of bond pads 18 located on the inactive surface 16 thereof as shown in the pattern shown in drawing FIG. 3. The semiconductor die 10 has the bond pads 14 on the active surface 12 thereof connected via connectors 24 to contact pads 22 of the substrate 20. A suitable sealant material 28 (shown on one side of the semiconductor die 10) may be used to seal the space 26 located between the semiconductor die 10 and substrate 20 around the sides of the semiconductor die 10 and/or a suitable underfill material 28′ (shown in an area) used to seal the space 26. Alternatively, portions 29 may be formed on the substrate 20 to engage any portions of a semiconductor die 10 when it is mounted on the substrate 20 to essentially eliminate the use of any sealants or underfill between the substrate 20 and the semiconductor die 10, although sealants may be used to seal any gap or space between portions 29 of the substrate 20 and the semiconductor die 10 as described hereinbefore with respect to sealant material 28 and underfill material 28′. The portions 29 may be formed by any suitable process, such as molding, stereolithographic techniques, etc. Further shown is a plurality of bond wires 30 used to connect any desired number of bond pads 18 on the inactive surface 16 of the semiconductor die 10 to desired contact pads 22 of the substrate 20 using a predetermined tension force applied through the bond wires 30 to help compensate for any stress in the semiconductor die 10. The bond wires 30 place forces on the semiconductor die 10 to help relieve or minimize any stresses and forces thereon or therein to help keep the semiconductor die 10 in a more stable configuration to minimize any tendency for the warping thereof or any physical dimensional changes thereto. The amount of force placed on the semiconductor die 10 through the bond wires 30 is subject to the characteristics, environment, and type of the semiconductor die 10. The bond wires 30 are used for mechanical stress management purposes regarding the semiconductor die 10, although the bond wires may be used for electrical connections as well. The bond wires 30 may be of any suitable material used for wire bonding to the bond pads 18 on the inactive side 16 of the semiconductor die 10. Any suitable conventional-type wire bonding apparatus may be used to form such bond wires 30 arrangements as may be needed.

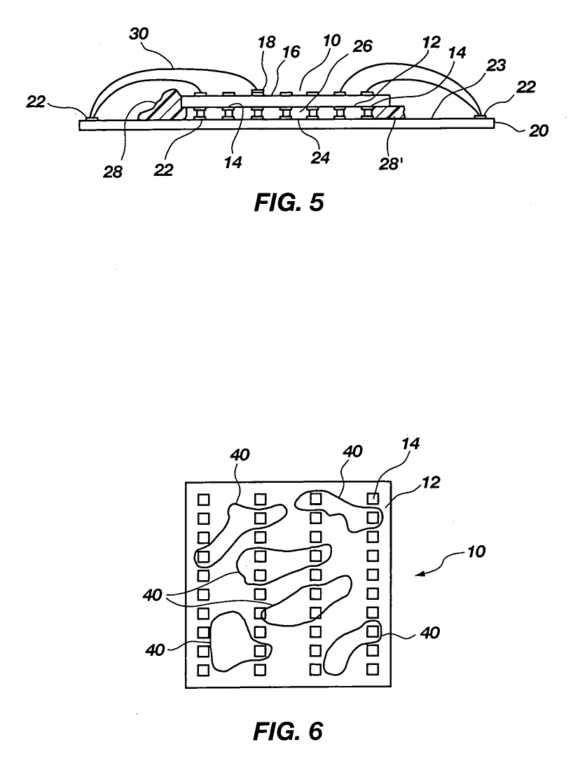

Referring to drawing FIG. 5, shown is a semiconductor die 10 located on a substrate 20 having a plurality of contact pads 22 located on a surface 23 thereof at desired locations. The contact pads 22 are connected to circuits (not shown) as desired. As shown, the semiconductor die 10 has a pattern of bond pads 14 located on the active surface 12 thereof, as shown in drawing FIG. 1. The semiconductor die 10 also has a plurality of bond pads 18 located on the inactive surface 16 thereof as shown in the pattern shown in drawing FIG. 3. The semiconductor die 10 has the bond pads 14 on the active surface 12 thereof connected via connectors 24 to contact pads 22 of the substrate 20. A suitable sealant material 28 may be used to seal the space 26 (shown on one side of the semiconductor die 10) located between the semiconductor die 10 and substrate 20 around the sides of the semiconductor die 10 and/or a suitable underfill material 28′ (shown in an area) used to seal the space 26. Further shown, a plurality of bond wires 30 is used to connect any desired number of bond pads 18 on the inactive surface 16 of the semiconductor die 10 to desired contact pads 22 of the substrate 20 to help compensate for stress in the semiconductor die 10. The bond wires 30 place forces on the semiconductor die to help relieve stresses thereon or therein to help keep the semiconductor die in a more stable configuration to minimize any tendency for the warping thereof or physical changes thereto. The amount of force placed on the semiconductor die 10 through the bond wires 30 is subject to the characteristics and environment of the semiconductor die 10. The bond wires 30 are being used for mechanical stress management purposes regarding the semiconductor die 10, although the bond wires may be used for electrical connections as well.

Referring to drawing FIG. 6, shown is the active surface 12 of a semiconductor die 10 having a plurality of bond pads 14 thereon located in a pattern of four columns of bond pads 14 as describe hereinbefore. Also shown are isothermal lines 40 illustrating areas having generally the same temperature therein during operation of the semiconductor die 10. The isothermal lines 40 may be used to indicate different temperature levels on different portions of the semiconductor die 10. The isothermal lines 40 generally indicate portions of a semiconductor die 10 where higher stresses will be present during the operation thereof. These higher stresses may be due to greater expansion of materials of those areas within any isothermal line due to high temperatures therein and any mismatch between the coefficients of thermal expansion of those materials with respect to each other. Also, the area within any isothermal line 40 illustrates an area of a semiconductor die where inherent stresses are present due to the architecture of any circuitry and component(s) contained therein and the materials used to form such circuitry and component(s).

Referring to drawing FIG. 7, shown is a portion of a semiconductor die 10 having a bond pad 18 on the inactive surface 16. The bond pad 18 may be formed of a plurality of layers 52, 54 of any suitable metal or a single layer of metal, each having a coefficient of expansion different from that of the material forming the semiconductor die 10. In this manner, when the bond pad 18 is subjected to heating during the operation of the semiconductor die 10, the area 56 of the semiconductor die 10 located under and adjacent the bond pad 18 is subjected to forces caused by the different coefficients of thermal expansion between the material of the semiconductor die 10 and the material(s) of the bond pad 18 to help minimize forces and stresses within the semiconductor die 10 tending to cause the shape and configuration of semiconductor die 10 to change.

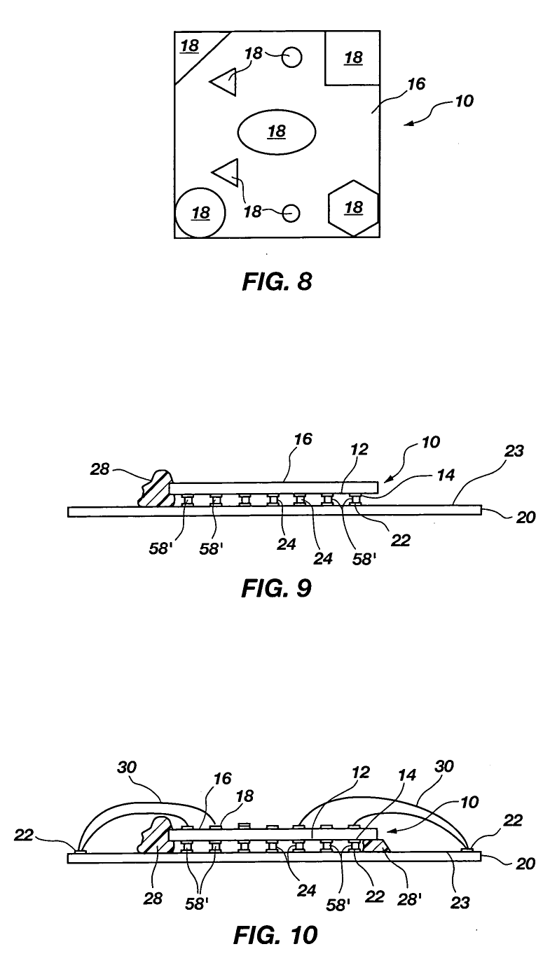

Referring to drawing FIG. 8, shown is a plurality of bond pads 18 located on the inactive surface 16 of a semiconductor die 10. The bond pads 18 may have any desired suitable shape, such as square, rectangular, circular, elliptical, hexagonal, triangular, etc., to help minimize forces and stresses that cause the shape and configuration of semiconductor die 10 to change during the operation thereof. The shape of the bond pad 18, the location of the pond pad 18 on the inactive surface 16 of the semiconductor die 10, the layers of material forming the bond pad 18, and the specific metal materials used to form the bond pad 18 are determined through the minimization of the forces thereunder and therearound on the semiconductor die 10 to help minimize any change in shape or configuration of the semiconductor die 10 during the operation thereof. Any area having a higher temperature than the surrounding area on the semiconductor die 10, such as an area within an isothermal line 40 as illustrated in drawing FIG. 6, is such an area where a bond pad 18 having a desired shape and number of layers of metal therein may be located. Alternatively, high stress areas of the semiconductor die 10 may be determined by any suitable method for the placement of bond pads 18 on the inactive surface 16 of the semiconductor die 10.

Referring to drawing FIG. 9, shown is a semiconductor die 10 located on a substrate 20 as described hereinbefore. The semiconductor die 10 has some of the bond pads 14 on the active surface 12 thereof connected via connectors 24 to contact pads 22 of the substrate 20. Other bond pads 14 of the semiconductor die 10 are connected to contact pads 22 of the substrate 20 using suitable solder balls 58 or suitable resilient polymer-type connectors 58′ to help to minimize the forces around bond pads 14 on the semiconductor die 10 to help minimize any change in shape or configuration of the semiconductor die 10 during the operation thereof. The bond pads 14 may not need to be connected to any circuit or component of the semiconductor die 10 but are used as a mechanism when connected to portions of the substrate 20 to distribute forces generated by the semiconductor die 10 to help prevent any change in shape or configuration thereof during the operation thereof. Depending upon the semiconductor die 10, the number of bond pads 14 used to distribute forces from the semiconductor die 10 to the substrate 20 varies as well as the type of solder balls 58 or resilient connectors 58′ used for the semiconductor die 10 and the substrate 20. A combination of solder balls 58 and resilient connectors 58′ may be used to more effectively distribute the forces from the semiconductor die 10 to the substrate 20. If desired, a suitable sealant material 28 or underfill material 28′ may be used around or between the semiconductor die 10 and substrate 20 as described hereinbefore. Alternatively, a portion 29 (shown in FIG. 4) may be included on the substrate 20, if desired, as well as any desired sealant material 28 or underfill material 28′ used therewith.

Referring to drawing FIG. 10, shown is a semiconductor die 10 located on a substrate 20 as described hereinbefore. The semiconductor die 10 has some of the bond pads 14 on the active surface 12 thereof connected via connectors 24 to contact pads 22 of the substrate 20. Other bond pads 14 of the semiconductor die 10 are connected to contact pads 22 of the substrate 20 using suitable solder balls 58 or suitable resilient polymer-type connectors 58′ to help minimize the forces around bond pads 14 on the semiconductor die 10 and in turn minimize any change in shape or configuration of the semiconductor die 10 during the operation thereof. The bond pads 14 may not need to be connected to any circuit or component of the semiconductor die 10 but are used as a mechanism when connected to portions of the substrate 20 to distribute forces generated by the semiconductor die 10 to help prevent any change in shape or configuration thereof during the operation thereof. Depending upon the semiconductor die 10, the number of bond pads 14 used to distribute forces from the semiconductor die 10 to the substrate 20 varies as well as the type of solder balls 58 or resilient connectors 58′ used for the semiconductor die 10 and the substrate 20. A combination of solder balls 58 and resilient connectors 58′ may be used to more effectively distribute the forces from the semiconductor die 10 to the substrate 20. Further shown, a plurality of bond wires 30 are used to connect any desired number of bond pads 18 on the inactive surface 16 of the semiconductor die 10 to desired contact pads 22 of the substrate 20 to help compensate for stress in the semiconductor die 10. The bond wires 30 place forces on the semiconductor die 10 to help relieve stresses thereon or therein to help keep the semiconductor die 10 in a more stable configuration, thereby minimizing warping thereof or physical changes therein. The amount of force placed on the semiconductor die 10 through the bond wires 30 is subject to the characteristics and environment of the semiconductor die 10. The bond wires 30 are used for mechanical stress management purposes regarding the semiconductor die 10, although the bond wires may be used for electrical connections as well. Alternatively, a portion 29 (shown in FIG. 4) may be included on the substrate 20, if desired, as well as any desired sealant material 28 or underfill material 28′ used therewith.

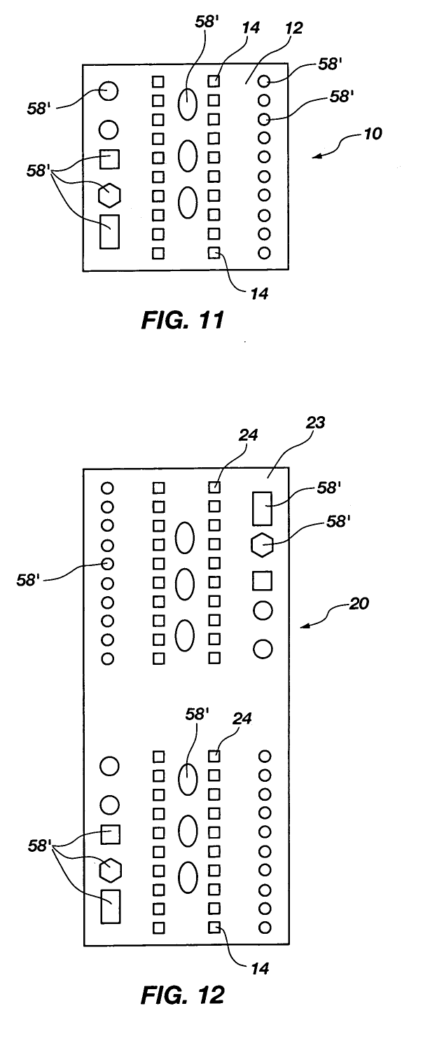

Referring to drawing FIG. 11, shown is a semiconductor die 10 having a plurality of bond pads 14 located on the active surface 12 as described hereinbefore. Also shown is a plurality of solder balls 58 and resilient connectors 58′ having various shapes, such as circular, ellipsoid, square, hexagonal, rectangular, etc., formed on the active surface 12 of the semiconductor die 10. As shown, the solder balls 58 and/or resilient connectors 58′ used to distribute forces from the semiconductor die 10 to a substrate 20, as described hereinbefore, may be located throughout the active surface 12 of the semiconductor die 10 having any desired shape at any desired location in relation to the location of the bond pads 14 on the active surface 12. Additionally, the resilient connectors 58′ may be single-layer or multilayer metal pads, such as those illustrated in drawing FIGS. 7 and 8 herein.

Referring to drawing FIG. 12, shown is a substrate 20 having a plurality of contact pads 22 located on a surface thereof and a plurality of resilient connectors 58′ having various shapes, such as circular, ellipsoid, square, hexagonal, rectangular, etc., formed on surface 23 for the distribution of forces from a semiconductor die 10 (not shown in this drawing figure but as shown and described regarding drawing FIGS. 9, 10, and 11 hereinbefore) when attached to a portion of the substrate 20 with solder balls 58 located between the bond pads 14 of the semiconductor die 10 and the contact pads 22 of the substrate 20. The resilient connectors 58′ may be formed on either the semiconductor die 10, the substrate 20, or on both the semiconductor die 10 and the substrate 20 to distribute the forces and stresses of the semiconductor die 10. Additionally, the resilient connectors 58′ may be single-layer or multilayer metal pads, such as those illustrated in drawing FIGS. 7 and 8 herein.

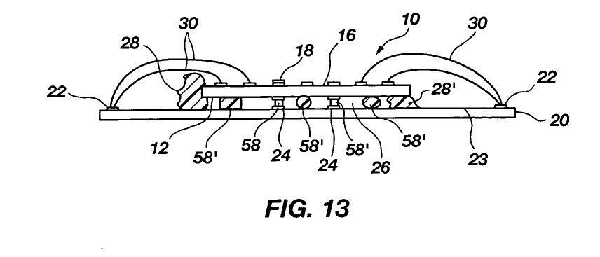

Referring to drawing FIG. 13, shown is a semiconductor die 10 having a plurality of bond pads 14 located on the active surface 12 thereof and a plurality of bond pads 18 located on the inactive surface 16 thereof. Also shown is a substrate 20 having a plurality of contact pads 22 located on a surface 23 thereof with a plurality solder balls 58 connecting bond pads 14 and contact pads 22 and a plurality of resilient connectors 58′ located in the space 26 contacting the active surface 12 of the semiconductor die 10 and the surface 23 of the substrate 20 to distribute stresses and forces from the semiconductor die 10 to the substrate 20. The resilient connectors 58′ may have any desired suitable shapes, as illustrated in drawing FIG. 11. Also shown is a plurality of bond wires 30 extending between the bond pads 18 on inactive surface 16 of the semiconductor die 10 and contact pads 22 on the substrate 20 to distribute stresses and forces from the semiconductor die 10 to the substrate 20. The bond pads 18 may be in any pattern as well as any shape as described hereinbefore and shown more specifically in, but not limited to, drawing FIGS. 1, 3, 7, and 8. In this manner, stresses and forces may be distributed from the semiconductor die 10 to the substrate 20 in a variety of manners to help minimize stresses and forces on the semiconductor die 10. A suitable sealant material 28 may be used to seal the space 26 (shown on one side of the semiconductor die 10) located between the semiconductor die 10 and substrate 20 and around the sides of the semiconductor die 10 and/or a suitable underfill material 28′ (shown in an area) used to seal the space 26. Alternatively, a portion 29 (shown in FIG. 4) may be included on the substrate 20, if desired, as well as any desired sealant material 28 or underfill material 28′ used therewith.

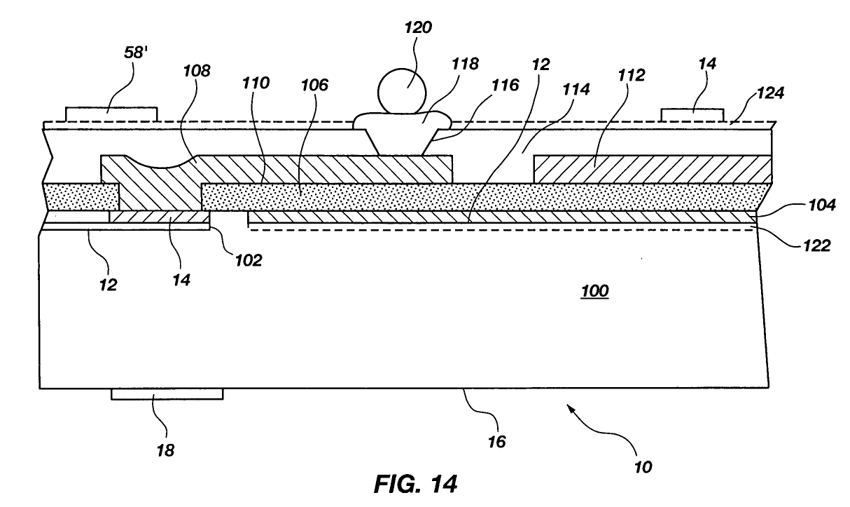

Referring to drawing FIG. 14, shown is a portion of a semiconductor die 10, such as a memory type semiconductor die having a plurality of memory arrays, which is fabricated using typical wafer level packaging or flip chip packaging process with the redistribution of bond pads of the semiconductor die to outer lead pads located over areas of the semiconductor die, such as areas of any type semiconductor die, to connect the traces formed in the redistribution metal layer to a suitable substrate. As shown in FIG. 14, the layer of metal used for redistributing bond pads on the semiconductor die can be further patterned to provide a protective ring and/or land areas over active semiconductor die areas, such as memory arrays in a memory type semiconductor die, and/or near the perimeter of the semiconductor die during the process forming the redistribution metal layer. This additional patterning does not add process steps because it is done in conjunction with the patterning for the metal traces for the redistribution of the bond pads for the semiconductor die. Such areas of metal may provide additional protection against debris impingement damage to the circuitry of semiconductor die 10 during back-end processing, testing, and final assembly of the semiconductor die, whether the semiconductor die is in wafer form or singulated package form. The areas of metal protection in the redistribution metal layer yields a more robust, higher yielding wafer level package or flip chip in package semiconductor die. Further, a final polyimide coating is usually applied over the redistribution metal layer which passivates the redistribution metal layer. The final polyimide layer providing additional protection from impingement and chipping damage of the semiconductor die. Additionally, the final polyimide passivation layer may be patterned to provide open areas over the desired areas of the redistribution metal layer which could then be plated, typically with a five micron layers of nickel and gold, during the under bump metallization process for the redistributed bond pads of the semiconductor die giving more protection for areas of the circuitry of the semiconductor die as well as better heat transfer characteristics for the semiconductor die and alpha particle radiation protection for the semiconductor die. As shown in drawing FIG. 14, a portion of a semiconductor die 10 having a semiconductor substrate 100, a bond pad 14 is connected to a portion of at least one circuit 102, a first metal protection layer 104, a suitable first passivation layer 106 located on portions of active surface 12 of the semiconductor die 10, a conductive layer 108 having a portion of traces or circuits formed thereof connected to the bond pad 14 and a portion located on the top surface 110 of first passivation layer 106, a second metal protection layer 112 located on portions of first passivation layer 106, a second passivation layer 114 covering the conductive layer 108 and the second metal protection layer 112 having an aperture 116 therein, a solder type-connector 118 located in the aperture 116 contacting a portion of conductive layer 108, and a solder ball 120 located on the solder-type connector 118. Any suitable materials may be used for the first passivation layer 106 and the second passivation layer 114 and applied by any suitable known processes used in semiconductor die manufacture. Any suitable metals or metal alloys may be used for the conductive layer 108, the first metal protection layer 104, and the second metal protection layer 112, as desired. Similarly, any suitable solder-type connector 118 may be used as well as solder ball 120 and applied by any suitable known processes in semiconductor manufacture. The conductive layer 108 and solder-type connectors 118 are used to locate solder balls 120 for connection to the bond pads 14 located on the active surface 12 to facilitate connecting the semiconductor die 10 to any desired substrate 20 (not shown). The second metal protection layer 112 is formed on any desired portion or portions of the semiconductor die 10 to protect the semiconductor die 10 from any damage, such as damage during molding or encapsulation thereof by the material used in such operations, to facilitate handling of the semiconductor die 10 by automated pick-and-place equipment by having a readily visible layer of material on desired portions of the semiconductor die 10, to protect any circuitry and/or components located under portions of the second metal protection layer 112 from unwanted forces being placed thereon as well as distribute forces being placed thereon for any purpose, and to facilitate heat transfer from the circuitry and/or components of the semiconductor die 10 located thereunder and adjacent thereto. If desired, any number of metal protection layers in addition to first metal protection layer 104 and second metal protection layer 112 may be used as may be accommodated in desired areas of the semiconductor die 10, such as is shown by dashed lines 122, to help protect the circuitry and/or components of the semiconductor die 10 as well as to help distribute stresses and forces acting on the semiconductor die 10. Similarly, any desired number of passivation layers may be used in addition to first passivation layer 106 and second passivation layer 114, such as is shown by dashed lines 124, as may be desired for additional protection for the semiconductor die 10 from damage due to foreign material and to help distribute stresses and forces on the semiconductor die 10. Also, shown on the portion of the semiconductor die 10 are one or more bond pads 18 on the inactive surface 16 thereof, bond pads 14, and one or more resilient pads 58′, such as discussed hereinbefore.

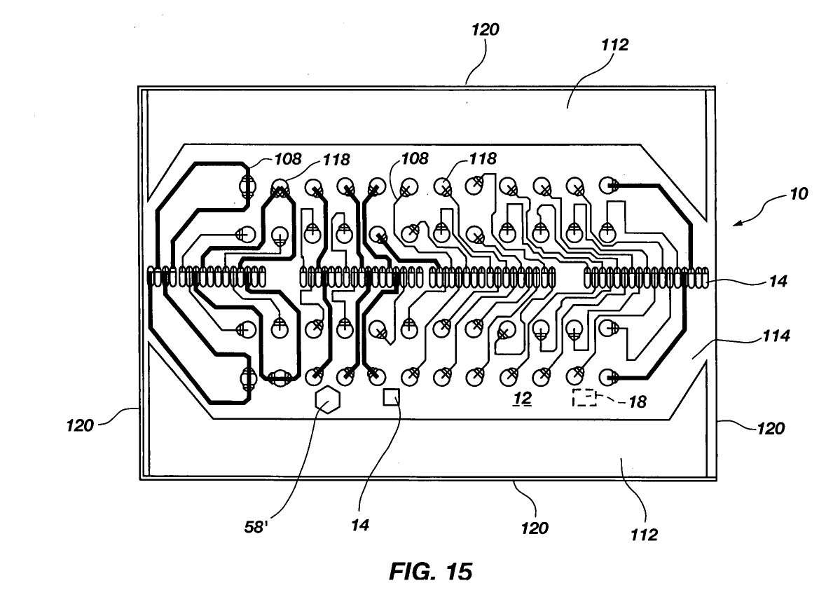

Referring to drawing FIG. 15, shown is a semiconductor die 10 as described hereinbefore regarding drawing FIG. 14. As shown, one or more metal protection layers 112 are formed on or adjacent the active surface 12 having a portion thereof located adjacent at least one edge 126 of the semiconductor die 10 to protect the semiconductor die 10 from damage during molding or encapsulation thereof by the material used in such operations, to facilitate handling of the semiconductor die 10 by automated pick-and-place equipment by having a readily visible layer of material on desired portions of the semiconductor die 10, to protect any circuitry and/or components located under portions of the second metal protection layer 112 from unwanted forces being placed thereon as well as distribute forces being placed thereon, and to facilitate heat transfer from the circuitry and/or components of the semiconductor die 10 located thereunder and adjacent thereto. Similarly, any desired number of passivation layers 114 may be formed on or adjacent the active surface 12 of the semiconductor die 10 for the various reasons set forth hereinbefore. Also, shown on the active surface 12 of the semiconductor die 10 are portions of conductive layer 108 forming traces from the bond pads 14 of the semiconductor die 10 to the solder-type connectors 118. In this manner, as previously described herein, one or more protection layers 112 and passivation layers 114 may be used to protect any desired portion(s) of the semiconductor die 10. Additionally, as described herein, bond pads 18 (shown in dashed lines) may be formed on the inactive surface of the semiconductor die 10 and other bond pads 14, such as described herein, and resilient connectors 58′ may be formed on the active surface 12 of the semiconductor die 10 for stress and other force management purposes as discussed hereinbefore.

It will be appreciated that various combinations of the stress and force management features may be used on any surface of a semiconductor die as set forth herein. Any combination of bond pads, resilient pads, metal protection layers, and passivation layers may be used as desired to help minimize stresses and forces on a semiconductor die.

1. A semiconductor die having at least one circuit connected to at least one component comprising:
a semiconductor die having an active surface, an inactive surface, and at least one circuit;
at least one bond pad formed on a portion of the active surface and connected to the at least one circuit; and
at least one bond pad formed on a portion of the inactive surface of the semiconductor die for at least one of lowering stress of a portion of the semiconductor die, protecting a portion of the semiconductor die, and lowering stress of a portion of the semiconductor die and protecting a portion of the semiconductor die.

2. The semiconductor die of claim 1, wherein the at least one bond pad formed on the portion of the inactive surface of the semiconductor die includes a bond pad connected to the at least one circuit of the semiconductor die.

3. The semiconductor die of claim 1, wherein the at least one bond pad formed on the portion of the inactive surface includes a bond pad having more than one layer of material.

4. The semiconductor die of claim 3, wherein the at least one bond pad formed on the portion of the inactive surface includes a bond pad having more than one layer of material, each layer of material having a coefficient of thermal expansion different from a coefficient of thermal expansion of another layer of material.

5. The semiconductor die of claim 1, further comprising:
a substrate having a portion thereof connected to the at least one bond pad formed on the portion of the active surface of the semiconductor die, the substrate having at least one circuit connected to the at least one bond pad formed on the active surface of the semiconductor die; and
at least one bond wire connected to the at least one pad formed on the portion of the inactive surface of the semiconductor die.

6. The semiconductor die of claim 5, wherein the substrate includes a portion thereof located adjacent at least one edge of the semiconductor die.

7. The semiconductor die of claim 5, further comprising a sealant material located between a portion of the semiconductor die and a portion of the substrate.

8. The semiconductor die of claim 5, further comprising a sealant material located along a portion of at least one edge of the semiconductor die and a portion of the substrate.

9. The semiconductor die of claim 5, wherein the:
at least one bond pad formed on the portion of the active surface is connected to a contact pad on a portion of a surface of the substrate.

10. The semiconductor die of claim 5, further comprising:
at least one resilient connector attached to a portion of the active surface of the semiconductor die and a portion of a surface of the substrate.

11. The semiconductor die of claim 1, further comprising:
at least one resilient connector attached to a portion of the active surface of the semiconductor die and a portion of a surface of a substrate.

12. The semiconductor die of claim 1, wherein the at least one bond pad formed on the portion of the inactive surface of the semiconductor die includes a shape of one of a square shape, rectangular shape, circular shape, elliptical shape, hexagonal shape, and triangular shape.

13. The semiconductor die of claim 10, wherein the at least one resilient connector includes a shape of one of a square shape, rectangular shape, circular shape, elliptical shape, hexagonal shape, and triangular shape.

14. The semiconductor die of claim 5, wherein the substrate includes at least one resilient connector located on a surface thereon abutting a portion of the semiconductor die.

15. The semiconductor die of claim 1, wherein the semiconductor die includes at least a portion of one metal protection layer located on a portion of the active surface of the semiconductor die.

16. The semiconductor die of claim 1, wherein the semiconductor die includes a first passivation layer located on a portion thereof and a second passivation layer located on a portion of the first passivation layer.

17. The semiconductor die of claim 1, wherein the semiconductor die includes at least a portion of one metal protection layer located on a portion of the active surface of the semiconductor die, a first passivation layer located on a portion of the one metal protection layer, and a second passivation layer located on a portion of the first passivation layer.

18. The semiconductor die of claim 1, wherein the semiconductor die includes at least a portion of more than one metal protection layer located on a portion of the active surface of the semiconductor die, a first passivation layer located on a portion on the metal protection layer, and a plurality of passivation layers located on at least a portion of the first passivation layer.

19. The semiconductor die of claim 1, wherein the semiconductor die includes a portion of at least one metal protection layer having a portion thereof located adjacent an edge of the semiconductor die.

20. The semiconductor die of claim 1, wherein the semiconductor die includes at least one trace extending from at least a portion of the at least one bond pad formed on the portion of the active surface of the semiconductor die.

21. The semiconductor die of claim 20, further comprising at least one connector located on a portion of the at least one trace.

22. A semiconductor die having at least one circuit connected to at least one component and a substrate comprising:
a semiconductor die having an active surface, an inactive surface and at least one circuit, the semiconductor die including at least one bond pad formed on a portion of the active surface thereof connected to the at least one circuit and at least one bond pad formed on a portion of the inactive surface for at least one of lowering stress of a portion of the semiconductor die, protecting a portion of the semiconductor die, and lowering stress of a portion of the semiconductor die and protecting a portion of the semiconductor die; and
a substrate having a portion thereof connected to the at least one bond pad formed on the portion of the active surface of the semiconductor die.

23. The semiconductor die and substrate of claim 22, wherein the at least one bond pad formed on the portion of the inactive surface of the semiconductor die includes a bond pad connected to the at least one circuit of the semiconductor die.

24. The semiconductor die and substrate of claim 22, wherein the at least one bond pad formed on the portion of the inactive surface includes a bond pad having more than one layer of material.

25. The semiconductor die and substrate of claim 24, wherein the at least one bond pad formed on the portion of the inactive surface includes a bond pad having more than one layer of material, each layer of material having a coefficient of thermal expansion different from a coefficient of thermal expansion of another layer of material.

26. The semiconductor die and substrate of claim 22, further comprising:
at least one bond wire connected to the at least one bond pad formed on the portion of the inactive surface of the semiconductor die.

27. The semiconductor die and substrate of claim 26, wherein the substrate includes a portion thereof located adjacent at least one edge of the semiconductor die.

28. The semiconductor die and substrate of claim 26, further comprising a sealant material located between a portion of the semiconductor die and a portion of the substrate.

29. The semiconductor die and substrate of claim 26, further comprising a sealant material located along a portion of at least one edge of the semiconductor die and a portion of the substrate.

30. The semiconductor die and substrate of claim 26, wherein the:
at least one bond pad formed on the portion of the active surface is connected to a contact pad on a portion of a surface of the substrate.

31. The semiconductor die and substrate of claim 26, further comprising:
at least one resilient connector attached to a portion of the active surface of the semiconductor die and a portion of a surface of the substrate.

32. The semiconductor die and substrate of claim 22, further comprising:
at least one resilient connector attached to a portion of the active surface of the semiconductor die and a portion of a surface of the substrate.

33. The semiconductor die and substrate of claim 22, wherein the at least one bond pad formed on the portion of the inactive surface of the semiconductor die includes a shape of one of a square shape, rectangular shape, circular shape, elliptical shape, hexagonal shape, and triangular shape.

34. The semiconductor die and substrate of claim 32, wherein the at least one resilient connector includes a shape of one of a square shape, rectangular shape, circular shape, elliptical shape, hexagonal shape, and triangular shape.

35. The semiconductor die and substrate of claim 26, wherein the substrate includes at least one resilient connector located on a surface thereof abutting a portion of the semiconductor die.

36. The semiconductor die and substrate of claim 22, wherein the semiconductor die includes at least a portion of one metal protection layer located on a portion of the active surface of the semiconductor die.

37. The semiconductor die and substrate of claim 22, wherein the semiconductor die includes a first passivation layer located on a portion thereof and a second passivation layer located on a portion of the first passivation layer.

38. The semiconductor die and substrate of claim 22, wherein the semiconductor die includes at least a portion of one metal protection layer located on a portion of the active surface of the semiconductor die, a first passivation layer located on a portion of the one metal protection layer, and a second passivation layer located on a portion of the first passivation layer.

39. The semiconductor die and substrate of claim 22, wherein the semiconductor die includes at least a portion of more than one metal protection layer located on a portion of the active surface of the semiconductor die, a first passivation layer located on a portion of the more than one metal protection layer, and a plurality of passivation layers located on at least a portion of the first passivation layer.

40. The semiconductor die and substrate of claim 22, wherein the semiconductor die includes a portion of at least one metal protection layer having a portion thereof located adjacent an edge of the semiconductor die.

41. The semiconductor die and substrate of claim 22, wherein the semiconductor die includes at least one trace extending from at least a portion of the at least one bond pad formed on the portion of the active surface of the semiconductor die.

42. The semiconductor die and substrate of claim 41, further comprising at least one connector located on a portion of the at least one trace.

43. A method of relieving forces on a semiconductor die comprising:
forming an area of metal on a surface of the semiconductor die for one of decreasing stress acting on the surface of the semiconductor die and protecting at least a portion of the semiconductor die.

44. The method of claim 43, further comprising;
providing a substrate;
connecting the area of metal to a portion of the substrate; and
applying a force between the substrate and the area of metal.

45. The method of claim 43, further comprising:
applying a layer of material to passivate a portion of the area of metal.

46. The method of claim 43, wherein the area of metal comprises at least one bond pad formed on a portion of an inactive surface of the semiconductor die connected to a circuit of the semiconductor die.

47. The method of claim 46, wherein the at least one bond pad formed on a portion of the inactive surface includes a bond pad having more than one layer of material.

48. The method of claim 47, wherein the at least one bond pad formed on a portion of the inactive surface includes a bond pad formed having more than one layer of material, each layer of material having a different coefficient of thermal expansion than another layer of material.

49. The method of claim 46, further comprising:
forming a substrate having a portion thereof connected to the at least one bond pad formed on a portion of the inactive surface of the semiconductor die, the substrate having at least one circuit connected to the at least one bond pad of the semiconductor die; and
at least one bond wire connected to the at least one bond pad formed on the inactive surface of the semiconductor die.

50. The method of claim 49, wherein the substrate includes a portion thereof located adjacent at least one edge of the semiconductor die.

51. The method of claim 49, further comprising applying a sealant material located between a portion of the semiconductor die and a portion of the substrate.

52. The method of claim 49, further comprising applying a sealant material located along a portion of at least one edge of the semiconductor die and a portion of the substrate.

53. The method of claim 49, further comprising:
connecting the at least one bond pad formed on the inactive surface to a contact pad on a portion of a surface of the substrate.

54. The method of claim 49, further comprising:
attaching at least one resilient connector to a portion of the active surface of the semiconductor die and a portion of a surface of the substrate.

55. The method of claim 49, wherein the at least one bond pad formed on the inactive surface of the semiconductor die includes a shape of one of a square shape, rectangular shape, circular shape, elliptical shape, hexagonal shape, and triangular shape.

56. The method of claim 49, wherein the substrate includes at least one resilient connector located on a surface thereon abutting a portion of the semiconductor die.

57. The method of claim 43, wherein the semiconductor die includes at least a portion of one metal protection layer located on a portion of an active surface thereof.

58. The method of claim 43, wherein the semiconductor die includes a first passivation layer located on a portion thereof and a second passivation layer located on a portion of the first passivation layer.

59. The method of claim 43, wherein the semiconductor die includes at least a portion of one metal protection layer located on a portion of an active surface thereof, a first passivation layer located on a portion of the one metal protection layer, and a second passivation layer located on a portion of the first passivation layer.

60. The method of claim 43, wherein the semiconductor die includes at least a portion of more than one metal protection layer located on a portion of an active surface thereof, a first passivation layer located on a portion of the more than one metal protection layer, and a plurality of passivation layers located on at least a portion of the first passivation layer.

61. The method of claim 43, wherein the semiconductor die includes a portion of at least one metal protection layer located adjacent an edge of the semiconductor die.

62. The method of claim 43, wherein the semiconductor die includes at least one trace extending from at least a portion of the area of metal formed on the surface of the semiconductor die.

63. The method of claim 62, further comprising at least one connector located on a portion of the at least one trace.

64. A method of forming a semiconductor die having at least one circuit connected to at least one component and a substrate comprising:
providing a semiconductor die having an active surface and an inactive surface, the semiconductor die including at least one bond pad formed on a portion of the active surface connected to the at least one circuit and at least one bond pad formed on a portion of the inactive surface for at least one of lowering stress of a portion of the semiconductor die, protecting a portion of the semiconductor die, and lowering stress of a portion of the semiconductor die and protecting a portion of the semiconductor die; and
attaching a substrate having a portion thereof connected to the at least one bond pad formed on the portion of the active surface of the semiconductor die.

65. The method of claim 64, wherein the at least one bond pad formed on the portion of the inactive surface of the semiconductor die includes a bond pad connected to a circuit of the semiconductor die.

66. The method of claim 64, wherein the at least one bond pad formed on the portion of the inactive surface includes a bond pad having more than one layer of material.

67. The method of claim 66, wherein the at least one bond pad formed on the portion of the inactive surface includes a bond pad having more than one layer of material, each layer of material having a different coefficient of thermal expansion than another layer of material.

68. The method of claim 64, further comprising:
connecting at least one bond wire to the at least one bond pad formed on the inactive surface of the semiconductor die.

69. The method of claim 68, wherein the substrate includes a portion thereof located adjacent at least one edge of the semiconductor die.

70. The method of claim 66, further comprising applying a sealant material located between a portion of the semiconductor die and a portion of the substrate.

71. The method of claim 66, further comprising applying a sealant material located along a portion of at least one edge of the semiconductor die and a portion of the substrate.

72. The method of claim 66, further comprising:
connecting the at least one bond pad formed on the portion of the active surface of the semiconductor die to a contact pad on a portion of a surface of the substrate.

73. The method of claim 66, further comprising:
attaching at least one resilient connector to a portion of the active surface of the semiconductor die and a portion of a surface of the substrate.

74. The method of claim 64, further comprising:
attaching at least one resilient connector to a portion of the active surface of the semiconductor die and a portion of a surface of the substrate.

75. The method of claim 64, wherein the at least one bond pad formed on the inactive surface of the semiconductor die includes a shape of one of a square shape, rectangular shape, circular shape, elliptical shape, hexagonal shape, and triangular shape.

76. The method of claim 74, wherein the at least one resilient connector includes a shape of one of a square shape, rectangular shape, circular shape, elliptical shape, hexagonal shape, and triangular shape.

77. The method of claim 68, wherein the substrate includes at least one resilient connector located on a surface thereon abutting a portion of the semiconductor die.

78. The method of claim 64, wherein the semiconductor die includes at least a portion of one metal protection layer located on a portion of the active surface thereof.

79. The method of claim 64, wherein the semiconductor die includes a first passivation layer located on a portion thereof and a second passivation layer located on a portion of the first passivation layer.

80. The method of claim 64, wherein the semiconductor die includes at least a portion of one metal protection layer located on a portion of the active surface thereof, a first passivation layer located on a portion of the one metal protection layer, and a second passivation layer located on a portion of the first passivation layer.

81. The method of claim 64, wherein the semiconductor die includes at least a portion of more than one metal protection layer located on a portion of the active surface thereof, a first passivation layer located on a portion of the more than one metal protection layer, and a plurality of passivation layers located on at least a portion of the first passivation layer.

82. The method of claim 64, wherein the semiconductor die includes a portion of at least one metal protection layer located adjacent an edge thereof.

83. The method of claim 64, wherein the semiconductor die includes at least one trace extending from at least a portion of the at least one bond pad formed on the active surface of the semiconductor die.

84. The method of claim 83, further comprising at least one connector located on a portion of the at least one trace.
